(19) United States
(12) Patent Application Publication
(10) Pub. No.: US 2025/0142735 A1
(43) Pub. Date: May 1, 2025

(54) APPARATUS AND METHOD OF PRINTING SOLDER ON PRINTED CIRCUIT BOARD FOR WARPAGE COMPENSATION

(71) Applicant: XILINX, INC., San Jose, CA (US)

(72) Inventor: Gamal REFAI-AHMED, Santa Clara, CA (US)

(73) Assignee: XILINX, INC., San Jose, CA (US)

(21) Appl. No.: 18/384,302

(22) Filed: Oct. 26, 2023

(51) Int. Cl. H05K 3/34; H05K 1/02; H05K 3/12; H05K 13/08

(52) U.S. Cl. CPC H05K 3/3485; H05K 1/0271; H05K 3/1233; H05K 13/082; H05K 2203/043

(57) ABSTRACT

A method of attaching a chip package to a printed circuit board (“PCB”) is provided, along with an electronic device fabricated using the method. The method includes measuring a warpage parameter of the chip package and selecting a stencil configured to compensate for warpage corresponding to the measured warpage parameter. The stencil includes a plurality of apertures. The selected stencil is positioned above the PCB, and solder paste is applied on the PCB via the plurality of apertures of the stencil. Thereafter, the PCB is moved away from the stencil. The chip package is positioned on the solder paste on the PCB, thereby attaching the chip package to the PCB.

### TECHNICAL FIELD

Embodiments of the present invention generally relate to apparatus and method of applying solder on a printed circuit board. More particularly, embodiments of the present invention generally relate to apparatus and method of applying solder on a printed circuit board to compensate for potential package warpage.

### BACKGROUND

The use of soldering is well known for forming electrical connections between electronic components such as semiconductor chips, chip carriers, modules, resistors, capacitors, etc. and the electrically conductive pads on the external surface of circuitized substrates such as printed circuit boards and chip carriers. One form of soldering involves using a stencil to apply the solder paste onto the circuitized substrate.

Stencil printing generally refers to the deposition of solder paste onto a bare printed circuit board (PCB). This is usually followed by mounting electronic components on the bare PCB and performing a solder reflow process. Typically, a stencil is positioned on top of the PCB. The stencil includes holes corresponding to the size and location of the pads on the PCB. Thereafter, solder paste is applied across the stencil to deposit the solder paste into the holes in the stencil. The stencil is removed before the electronic component is attached to the PCB via the solder paste.

Traditionally, the stencil is configured to be used with a specific electronic component to be added to the PCB. During assembly, the same stencil is used to apply solder paste on each PCB receiving that electronic component. While these electronic components have the same specifications, these differences may exist between each of these electronic components due to manufacturing tolerances to enable higher accepted manufacturing yield. For example, electronic components such as chip packages may have a range of coplanarity at room temperature that can vary from its average by 20% to 30%, but still meeting the required specifications. In some instances, these differences may lead to different amounts of warpage of the chip package during processing. Warpage in chip packages may cause joint failure, reduced lifetime of the components, or poor device performance.

Therefore, a need exists for an apparatus and method of applying solder on a printed circuit board to compensate for potential chip package warpage.

### SUMMARY

A method of attaching a chip package to a printed circuit board (“PCB”) and an electronic device fabricated using the method are provided. In one example, the method includes measuring a warpage parameter of the chip package and selecting a stencil configured to compensate for warpage corresponding to the measured warpage parameter. The stencil includes a plurality of apertures. The selected stencil is positioned above the PCB, and solder paste is applied on the PCB via the plurality of apertures of the stencil. Thereafter, the PCB is moved away from the stencil. The chip package is positioned on the solder paste on the PCB, thereby attaching the chip package to the PCB.

A method of attaching a chip package to a printed circuit board (“PCB”) is provided in another example. The method includes measuring a warpage parameter of the chip package. A first stencil is selected from a plurality of stencils. The first stencil is configured to compensate for warpage corresponding to the measured warpage parameter. The first stencil including a plurality of first apertures. The selected first stencil is positioned above the PCB, and solder paste is applied on the PCB via the plurality of first apertures of the first stencil. After moving the PCB away from the first stencil, the chip package is positioned on the solder paste on the PCB, thereby attaching the chip package to the PCB.

In one example, a method of attaching a chip package to a printed circuit board (“PCB”) includes measuring a warpage parameter of a first chip package; selecting a stencil configured to compensate for the warpage corresponding to the measured warpage parameter, the stencil including a plurality of apertures; positioning the stencil above the PCB; applying solder paste on the PCB via the plurality of apertures of the stencil; moving the PCB away from the stencil; and positioning a second chip package on the solder paste on the PCB, thereby attaching the second chip package to the PCB.

In another example, a method of attaching a chip package to a printed circuit board (“PCB”) includes measuring a warpage parameter of the chip package; selecting a first stencil from a plurality of stencils, the first stencil configured to compensate for warpage corresponding to the measured warpage parameter, the first stencil including a plurality of first apertures; positioning the first stencil above the PCB; applying solder paste on the PCB via the plurality of first apertures of the first stencil; moving the PCB away from the first stencil; and positioning the chip package on the solder paste on the PCB, thereby attaching the chip package to the PCB.

In yet another example, an electronic device is provided that includes a printed circuit board (PCB) electrically and mechanically connected to a first chip package. The first chip package has a first predetermined warpage characteristic. The PCB includes a first stenciled material disposed thereon that is patterned based on the first predetermined warpage characteristic of the first chip package.

In some examples, the first predetermined warpage characteristic is determined using a second chip package.

In some examples, the first predetermined warpage characteristic is at least one of stress or warpage analysis of the second chip package.

In still other examples, the electronic device additionally includes a second chip package having a second predetermined warpage characteristic. The second chip package is electrically and mechanically connected to the chip package. The PCB additionally includes a second stenciled material disposed thereon that is patterned based on the second predetermined warpage characteristic of the second chip package, wherein the first and second predetermined warpage characteristics are different.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a flow diagram of a method of attaching a chip package to a printed circuit board.

FIG. 2 is a schematic representation of one example of attaching the chip package to the printed circuit board of FIG. 1.

FIG. 3 is a schematic view of a chip package suitable for attachment to the printed circuit board of FIG. 1.

To facilitate understanding, identical reference numerals have been used, where possible, to designate identical elements that are common to the figures. It is contemplated that elements of one embodiment may be beneficially incorporated in other embodiments.

### DETAILED DESCRIPTION

A method of attaching a chip package to a printed circuit board (“PCB”) is provided. The method includes measuring a warpage parameter of the chip package and selecting a stencil configured to compensate for warpage corresponding to the measured warpage parameter. The method advantageously selects the appropriate stencil tailored to compensate for the warpage expected from each chip package. The stencil includes a plurality of apertures. The selected stencil is positioned above the PCB, and solder paste is applied on the stencil and the PCB via the plurality of apertures. Thereafter, the stencil is removed from the PCB. The chip package is positioned on the solder paste on the PCB, thereby attaching the chip package to the PCB.

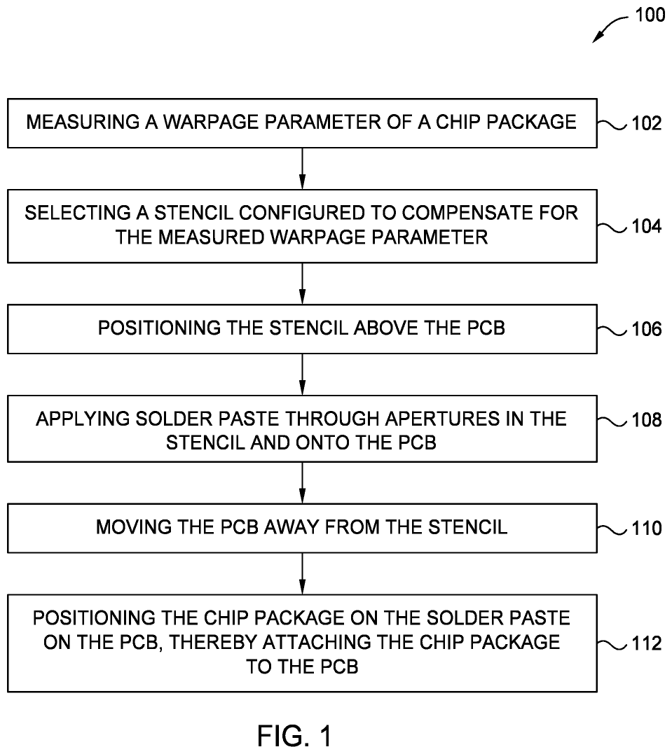

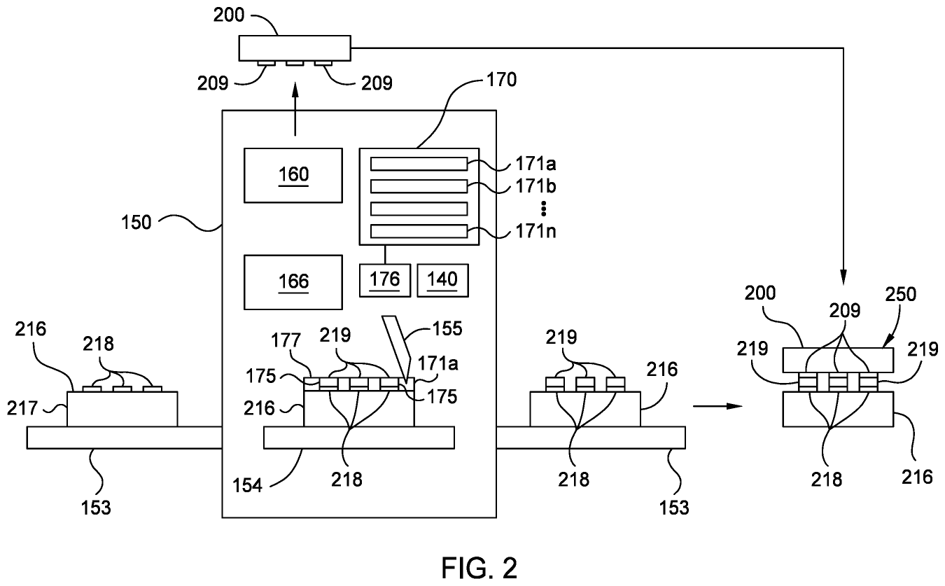

Turning now to FIG. 1, a flow diagram of a method 100 for attaching a chip package to a printed circuit board (“PCB”) is provided, according to some embodiments. FIG. 2 is a schematic representation of one example of the PCB during different stages of fabrication according to the method 100 of FIG. 1. In some embodiments, the method may be used to assemble a plurality of chip packages meeting the same technical specifications to a respective PCB.

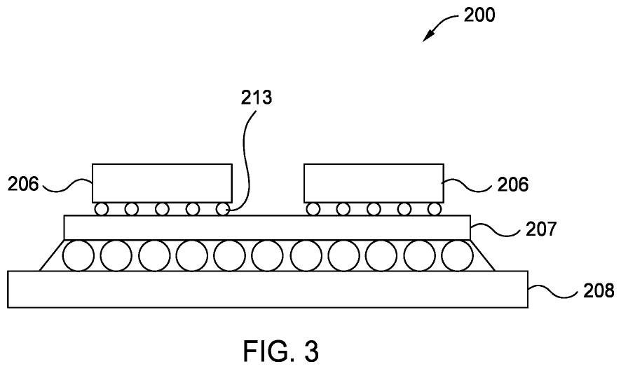

The method 100 begins at operation 102 by measuring a warpage parameter of the chip package 200 to be attached to the PCB 216. FIG. 3 illustrates an exemplary embodiment of the chip package 200. The chip package 200 includes one or more integrated circuit (IC) dies 206 and a package substrate 208. In this example, two integrated circuit dies 206 are electrically and mechanically mounted to the package substrate 208. Optionally, the integrated circuit dies 206 may be electrically and mechanically mounted to an interposer 207, with the interposer 207 electrically and mechanically mounted to the package substrate 208. Each chip package may include any suitable number of IC dies 206 that may fit on the package substrate 208, such as three, six, or eight IC dies. Examples of IC dies 206 that may be utilized in the chip package 200 include, but are not limited to, logic and memory devices, such as field programmable gate arrays (FPGA), application-specific integrated circuits (ASICs), memory devices, such as high band-width memory (HBM), optical devices, processors or other IC logic or memory structures. One or more of the IC dies 206 may optionally include optical devices such as photo-detectors, lasers, optical sources, and the like.

Functional circuitry of the IC dies 206 is connected to the circuitry of the package substrate 208 through the solder connections 213 or other suitable electrical connection, such as a hybrid connecter comprised of metal circuit connection material disposed in a dielectric sheet.

The chip package 200 is configured to be attached to the PCB 216. In the example shown in FIG. 2, the PCB 216 includes at least substrate 217 and a plurality of pads 218 disposed on a top surface of the substrate 217. The substrate 217 may be formed of prepeg material, which generally includes a base material, such as glass fabric impregnated with resin, and may be compressed and laminated with layers of patterned metal or other conductors. The plurality of pads 218 may be formed by patterning a conductive layer and etching the conductive layer using photolithography. The plurality of pads 218 may be formed of various electrically and/or thermally conductive materials, such as copper (Cu), silver (Ag), gold (Au), or nickel (Ni). The pads 218 are arranged so that various components, such as surface mount technology (“SMT”) components and flip chip components, may be electrically and/or mechanically attached to the substrate 217 via the pads 218. The PCB 216 may include any suitable number of pads 218 on its upper surface for coupling with one or more electric components, such as chip package 200.

In one embodiment, a warpage parameter of the chip package 200 to be attached to the PCB 216 is measured. The warpage parameter of the chip package 200 may be used to attach other attach other chip packages of the same type to the PCB 216 in lieu of the chip package 200 from which the warpage parameter was first determined. An exemplary warpage parameter is the thickness of the chip package 200. The thickness of the chip package 200 is believed to have a correlation with the amount of warpage the chip package 200 may experience during processing, such as during a reflow process to attach the chip package 200 to the PCB 216. The thickness of the chip package 200 may be measured using an optical measurement system 160, which may be commercially available from Optical Gaging Products. In another embodiment, the warpage may be determined using a shadow moiré measurement. In this example, the optical measurement system 160 may be integrated with a stencil printing machine 150. An exemplary stencil printing machine 150 is a NeoHorizon printer, which is commercially available from ASMPT SMT Solutions. In some examples, the optical measurement system 160 is an independent system in communication with the stencil printing machine 150. A controller 140 for the stencil printing machine 150 may instruct the optical measurement system 160 to measure the thickness of the chip package 200 and may receive the measured thickness from the optical measure system 160.

In one embodiment, the stencil printing machine 150 also includes a conveyor 153 for moving the PCB 216 into and out of the stencil printing machine 150. A support assembly 154 inside the stencil printing machine 150 may support the PCB 216 and position the PCB 216 for solder printing. In one example, the support assembly 154 may raise or lower the PCB 216 relative to the squeegee 155 for applying the solder paste.

At operation 104, a stencil 171 corresponding to the measured warpage parameter (e.g., thickness) is selected. In one example, the stencil 171a is selected from a stencil storage 170 containing a plurality of stencils 171a-n. The stencil storage 170 may be disposed in or connected to the stencil printing machine 150. The plurality of stencils 171a-n may be configured to compensate for the potential warpage of the chip package 200 represented by the measured thickness. In particular, each of the stencils 171a-n is configured to compensate for the potential warpage of a particular thickness of the chip package 200. For example, stencil 171a may be configured for use with a chip package 200 having a measured thickness of 6.0 mil. Similarly, stencil 171b may be configured for use with a chip package 200 having a measured thickness of 6.5 mil. Stencil 171c may be configured for use with a chip package 200 having a measured thickness of 7 mil, and so forth. The stencil storage 170 may contain any suitable number of stencils 171a-n for a desired thickness range. The stencils 171a-n may be generated for any suitable thickness increments, such as 1 mil, 0.5 mil, 0.33 mil, or 0.25 mil increments, within the desired thickness range.

In one embodiment, the stencils 171a-n in the stencil storage 170 include apertures 175 that are configured to compensate for the potential warpage of the chip package 200. In one example, the size of the apertures 175 are adjusted to compensate for the potential warpage of the chip package 200. In one embodiment, the stencils 171a-n in the stencil storage 170 are generated based on warpage data obtained from different chip package and PCB 216 assemblies. In one example, stencils having different levels of warpage compensation are used for each chip package thickness increment. The stencil providing the best warpage compensation is identified for each thickness increment of the chip package. The chosen stencils are disposed in the stencil storage 170 and may be selected for use with an incoming chip package having an equivalent measured thickness increment (e.g., warpage).

In one embodiment, the warpage data for the stencils 171a-n may be stored in a warpage database 176 of the stencil storage 170 for selecting the appropriate stencil 171a-n for the incoming chip packages 200. The measured warpage of the incoming chip package 200 will be compared to the warpage database 176 by the controller 140. Based on the comparison, the controller 140 will select the stencil 171a-n for the corresponding measured warpage for compensating the warpage of the incoming chip package 200.

In one embodiment, the stencils 171a-n have different sized apertures 175 to compensate for different amounts of warpage. In one example, the size of the apertures 175 based on amount of warpage compensation. For example, the size of the apertures 175 for a chip package 200 having a 6 mil thickness is based on the warpage data obtained for the chip package 200 having the same thickness. Similarly, the size of the apertures 175 for a chip package 200 having a 7 mil thickness is based on the warpage data obtained for the chip package 200 having the same thickness. In one embodiment, the size of the apertures 175 for the stencils 171a-n is a function of the package warpage range, the package ball grid array (“BGA”) size range, the BGA pitch, the thickness of the cap (if it is placed in the BGA side). In one example, a stencil for a chip package 200 having a coplanarity of 12 mil at room temperature, with 1 mm pitch, and BGA diameter of 25 mil may include apertures 175 with sizes ranging from 80% to 120% of the BGA diameter. In some examples, the apertures 175 in a stencil 171a-n configured for a chip package 200 having a thinner profile (e.g., 6.5 mil) may have a larger diameter than the apertures 175 in a stencil 171a-n configured for a chip package 200 having a thicker profile (e.g., 7.0 mil). In turn, the apertures 175 in a stencil 171a-n configured for a chip package 200 having an incrementally thicker profile (e.g., 7.5 mil) may have a larger diameter than the apertures 175 in the stencil 171a-n configured for the 7.0 mil profile.

In another embodiment, the stencils 171a-n can have uniform large or small apertures or a non-uniform mix of large and small apertures 175 for a chip package 200 having a plurality of warpage profiles. In this respect, a suitable stencil 171a-n may be selected to provide an appropriately sized solder paste to compensate for the measured warpage of the chip package 200. In one example, the stencil 171a-n for a particular thickness may include apertures 175 of the same or different sizes. For example, apertures 175 in locations of the stencil 171a-n that may experience more warpage may be larger in size than apertures 175 in locations of the same stencil 171a-n that may experience less warpage. In some embodiments, the stencils 171a-n include apertures 175 of one, two, three, four, or more different sizes.

In addition to or alternatively, the stencil 171a-n for a thinner profiled chip package 200 may have more larger sized apertures 175 than a stencil 171a-n for a thicker profiled chip package 200. For example, if the stencils 171a-n include apertures 175 of two different sizes, the thinner profiled stencil 171a-n may have more of the larger sized apertures 175. In another example, a stencil 171a-n for a chip package 200 having a thinner profile (e.g., 6.5 mil thickness) may have larger sized apertures 175, more large sized apertures 175, or both, than a stencil 171a-n for a chip package 200 having a thicker profile, such as 7.0 mil thickness. In one example, the size of the apertures 175 and/or the number of large sized apertures 175 may be used in configuring the stencils 171a-n for each thickness increment. In some embodiments, the apertures 175 located near an area experiencing more warpage may have larger apertures 175, more large sized apertures 175, or both.

In one example, the stencils 171a-n may be formed by machining or laser etching a sheet of metal. Exemplary metals include steel, nickel, nickel alloy, or other suitable materials. The stencils 171a-n may have a thickness of about 2 to 8 mils. In some examples, the stencils 171a-n configured for the same chip package 200 may have the same or substantially the same thickness, such 3 mil, 4 mil, or 5 mil. The stencils 171a-n include apertures 175 corresponding to the location of the pads 218 on the PCB 216 for connection with the chip package 200 or other electric components. In some embodiments, the stencils 171a-n include apertures 175 for more than one component to be added to the PCB 216. The apertures 175 may correspond to some or all of the pads 218 on the PCB 216, depending on the number and type of components to be added to the PCB 216. The apertures 175 may have any suitable cross-section, such as circular or oval.

At operation 106, the selected stencil 171a is retrieved from the stencil storage 170 and positioned above the printing location of the PCB 216 in the stencil printing machine 150. In one example, the selected stencil 171a is positioned above the printing location before the PCB 216 enters the stencil printing machine 150. In this instance, after entering the stencil printing machine 150, the PCB 216 is moved to the printing position below the selected stencil 171a. In some examples, the PCB 216 is optionally clamped or suitably held against the selected stencil 171a. In another example, the PCB 216 enters the stencil printing machine 150 before the selected stencil 171a is loaded above the printing location. At the printing location, the apertures 175 of the stencil 171a are aligned with the pads 218 of the PCB 216. In some embodiments, the selected stencil 171a-n is the same stencil 171a-n that was used to print solder paste on the previous chip package 200. In this instance, the previous stencil 171a-n can be re-used as the selected stencil 171a for the next chip package. In another example, the previous stencil is replaced with a new stencil 171a. In some examples, the selected stencil 171a will remain inside the stencil printing machine 150 for the duration of the PCB 216 assembly.

At operation 108, solder paste 219 is urged into the apertures 175 of the stencil 171a and onto the PCB 216. The solder paste 219 may be obtained from a solder paste source 166 located within the stencil printing machine 150. In one embodiment, the solder paste 219 is initially dispense on a top surface 177 of the stencil 171a. Thereafter, a squeegee 155 is used to wipe the solder paste 219 on the top surface 177 of the stencil 171. The squeegee 155 forces the solder paste 219 into the apertures 175 of the stencil 171a and against the top surface of the PCB 216. In this manner, the solder paste 219 is transferred from the top surface 177 of the stencil 171a, through the apertures 175, and onto the PCB 216. In some embodiments, the solder paste 219 may be a mixture of solder and flux.

At operation 110, after wiping the solder paste 219, the PCB 216 is moved away from stencil 171a and moved out of the stencil printing machine 150. The solder paste 219 disposed in the apertures 175 remain on the PCB 216 for contact with the chip package 200. The PCB 216 may be moved out of the stencil printing machine 150 using the conveyor 153. In some embodiments, a solder paste inspection may be performed after removal of the stencil 171a. The solder paste inspection may include applying light to the solder paste 219 and analyzing the reflection of the light to identify defects or to check for alignment of the solder paste 219 on the pads 218.

At operation 112, the chip package 200 is positioned on the printed solder paste 219. The pads 209 on the chip package 200 are aligned with the corresponding solder paste 219 and pads 218 on the PCB 216. In some embodiments, a reflow process is performed to attach the chip package 200 to the PCB 216, thus forming an electronic device 250.

In some embodiments, the method 100 is repeated for the next chip package 200. In some embodiments, operation 102 may be performed to measure the warpage parameter for the next chip package 200 before the previous chip package 200 has completed operation 112. For example, the thickness of the next chip package 200 may be measured while the previous chip package 200 is undergoing operation 104, operation 106, or operation 108,

While the above examples are described with respect to attaching a chip package 200 to a PCB 216, embodiments of the present disclosure are equally applicable to attaching a SMT component and/or flip chip components.

A method of attaching a chip package to a printed circuit board (“PCB”) is provided. The method includes measuring a warpage parameter of the chip package and selecting a stencil configured to compensate for warpage corresponding to the measured warpage parameter. The stencil includes a plurality of apertures. The selected stencil is positioned above the PCB, and solder paste is applied on the PCB via the plurality of apertures of the stencil. Thereafter, the PCB is moved away from the stencil. The chip package is positioned on the solder paste on the PCB, thereby attaching the chip package to the PCB.

A method of attaching a chip package to a printed circuit board (“PCB”) is provided. The method includes measuring a warpage parameter of the chip package. A first stencil is selected from a plurality of stencils. The first stencil is configured to compensate for warpage corresponding to the measured warpage parameter. The first stencil including a plurality of first apertures. The selected first stencil is positioned above the PCB, and solder paste is applied on the PCB via the plurality of first apertures of the first stencil. After moving the PCB away from the first stencil, the chip package is positioned on the solder paste on the PCB, thereby attaching the chip package to the PCB.

While the foregoing is directed to embodiments of the present invention, other and further embodiments of the invention may be devised without departing from the basic scope thereof, and the scope thereof is determined by the claims that follow.

What is claimed is:

1. A method of attaching a chip package to a printed circuit board (“PCB”), comprising:
measuring a warpage parameter of a first chip package;
selecting a stencil configured to compensate for the warpage corresponding to the measured warpage parameter, the stencil including a plurality of apertures;
positioning the stencil above the PCB;
applying solder paste on the PCB via the plurality of apertures of the stencil;
moving the PCB away from the stencil; and
positioning a second chip package on the solder paste on the PCB, thereby attaching the second chip package to the PCB.

2. The method of claim 1, wherein the warpage parameter is a thickness of the first chip package.

3. The method of claim 1, wherein the stencil is a first stencil selected from a plurality of stencils disposed in a stencil storage.

4. The method of claim 3, wherein the first stencil includes a first aperture having a size that is different than a second aperture of a second stencil.

5. The method of claim 4, wherein the first aperture and the second aperture are in the same location on their respective stencils.

6. The method of claim 4, wherein each of the plurality of stencils includes the same number of apertures.

7. The method of claim 4, wherein the first stencil includes a third aperture having a size that is different than the first aperture.

8. The method of claim 3, wherein the plurality of stencils have a substantially same thickness.

9. The method of claim 1, further comprising:
selecting a second stencil based on a warpage parameter of a third chip package;
positioning the second stencil above the PCB;
applying solder paste on the PCB through the second stencil;
moving the second PCB away from the second stencil; and
positioning the second chip package on the solder paste on the PCB, thereby attaching the second chip package to the PCB.

10. The method of claim 9, wherein the first chip package, the second chip package, and the third chip package meet a same set of technical specifications.

11. The method of claim 1, further comprising performing a reflow process after positioning the chip package on the PCB.

12. The method of claim 1, wherein the plurality of apertures of the stencil correspond to a plurality of pads of the PCB for connection with the first chip package.

13. A method of attaching a chip package to a printed circuit board (“PCB”), comprising:
measuring a warpage parameter of the chip package;
selecting a first stencil from a plurality of stencils, the first stencil configured to compensate for warpage corresponding to the measured warpage parameter, the first stencil including a plurality of first apertures;
positioning the first stencil above the PCB;
applying solder paste on the PCB via the plurality of first apertures of the first stencil;
moving the PCB away from the first stencil; and
positioning the chip package on the solder paste on the PCB, thereby attaching the chip package to the PCB.

14. The method of claim 13, wherein the plurality of stencils include a second stencil including a plurality of second apertures having a different size than the plurality of first apertures.

15. The method of claim 14, wherein the second stencil is configured to compensate for warpage corresponding to a second measured warpage parameter.

16. The method of claim 13, wherein number of apertures and a thickness of each of the plurality of stencils is about the same.

17. An electronic device comprising:
a first chip package having a first predetermined warpage characteristic; and
a printed circuit board (PCB) electrically and mechanically connected to the first chip package, the PCB comprising a first stenciled material disposed thereon that is patterned based on the first predetermined warpage characteristic of the first chip package.

18. The electronic device of claim 17, wherein the first predetermined warpage characteristic is determined using a second chip package.

19. The electronic device of claim 18, wherein the first predetermined warpage characteristic is at least one of stress or warpage analysis of the second chip package.

20. The electronic device of claim 17 further comprising:
a second chip package having a second predetermined warpage characteristic electrically and mechanically connected to the chip package, the PCB comprising a the PCB comprising a second stenciled material disposed thereon that is patterned based on the second predetermined warpage characteristic of the second chip package, wherein first and second predetermined warpage characteristics are different.
